(19) United States
(12) Patent Application Publication
(10) Pub. No.: US 2012/0256095 A1
(43) Pub. Date: Oct. 11, 2012

(54) RADIOGRAPHIC DEVICE AND MANUFACTURING METHOD THEREOF

(75) Inventors: Haruyasu NAKATSUGAWA, Kanagawa (JP); Yasuhisa KANEKO, Kanagawa (JP)

(73) Assignee: FUJIFILM CORPORATION, Tokyo (JP)

(21) Appl. No.: 13/438,448

(22) Filed: Apr. 3, 2012

(30) Foreign Application Priority Data
Apr. 6, 2011 (JP) 2011-084511

(51) Int. Cl. G01T 1/20; H01L 31/18; G01T 1/202

(52) U.S. Cl. 250/368; 438/69; 438/65; 257/E31.127

(57) ABSTRACT

In a radiation detector, a scintillator converts radiations penetrating through a sensor panel to light, and the light is detected by a photosensor in the sensor panel. A reflector layer including a specular reflection and retro-reflection layers is provided on the opposite side of the scintillator to the sensor panel. The specular reflection layer specularly reflects short-wavelength components of the light from the scintillator, and lets long-wavelength components of the light pass through it. The photosensor can detect the short-wavelength components efficiently at positions close to their origins because they are guided along columnar crystals of the scintillator. Since long-wavelength components are less refrangible and tend to deviate from their origins, causing crosstalk, the retro-reflection layer retroreflects the long-wavelength components toward the sensor panel, so that the long-wavelength components also reach the sensor panel at positions close to their origins.

### BACKGROUND OF THE INVENTION

1. Field of the Invention

The present invention relates to a radiographic device that is provided with a scintillator for converting radioactive rays into light and a sensor panel for detecting the light obtained from the radioactive rays through the conversion at the scintillator. More particularly, the radiographic device has a reflector layer for reflecting the converted light from the scintillator toward the sensor panel. The present invention relates also to a method of manufacturing the radiographic device.

2. Description of the Related Art

Radiographic devices using a radiation detector of indirect-conversion type have been used in practice. The indirect-conversion type radiation detector has a scintillator for converting incident radiations, such as x-rays, into visible or UV light, and a sensor panel opposed to the scintillator so as to detect the light obtained through the conversion in the scintillator. Thus the radiographic device acquires a radiographic image from the incident radiations. In order to make full use of the light from the scintillator, some conventional radiographic devices have a reflector layer on the opposite side of the scintillator to the sensor panel. The reflector layer has a specular mirror surface for reflecting the light radiated from the scintillator toward the sensor panel, as disclosed for example in JPA 2007-271504.

One scintillator may be fabricated through vapor deposition of CsI (cesium iodide) and the like on a substrate, to form an array of CsI columnar crystals, which are oriented in the light emitting direction of the scintillator. The columnar crystals serve as light guides in the scintillator; the light generated in response to the incident radiations in the scintillator will be directed toward the sensor panel through full-reflection inside the columnar crystals. Because the scattering of light from the scintillator is thus suppressed, the radiographic device using the columnar crystal scintillator is effective to prevent an adverse effect of the scattering on the resolution of the acquired radiographic image.

It is known in the art that columnar crystals of the scintillator are spaced from each other for prevention against crosstalk. Crosstalk is a phenomenon in which a portion of light traveling inside one columnar crystal transfers to an adjoined or adjacent columnar crystal. If the crosstalk occurs in the scintillator, a light ray generated inside the scintillator in response to an incident radioactive ray will get to the sensor panel at a point far from the original incident point of the radioactive ray. As a result, the acquired radiographic image will be blurred.

The crosstalk can occur even where the columnar crystals are not in contact with each other. Referring to FIG. 13, columnar crystals 121 of a scintillator 120 are schematically illustrated. Light 122 passing along inside one columnar crystal 121a will exit from the columnar crystal 121a when the incident angle θx onto the internal surface of the columnar crystal 121a gets equal to or less than a critical angle θc. Then the light 122 enters an adjacent columnar crystal 121b. Assuming that the columnar crystal of CsI has refractive index of 1.8, and that the air existing in between the columnar crystals 121 has refractive index of 1.0, the critical angle θc is approximately 34°.

The light 122 exiting from the columnar crystal 121a and entering the columnar crystal 121b may further exit from the columnar crystal 121b and penetrate through those columnar crystals which are distant from the columnar crystal 121b. This is because the gaps between the columnar crystals 121 are so narrow that the light 122 from the columnar crystal 121a will hardly be refracted. Particularly, long wavelength components 122b of the light 122 are less refrangible than short wavelength components 122a. Therefore, the light 122 exiting from the columnar crystal 121a may keep the incident angle less than the critical angle θc to other columnar crystals 121.

Not only light radiated directly from the scintillator toward the sensor panel but also light reflected from the reflector layer toward the sensor panel can suffer the crosstalk when its incident angle gets less than the critical angle. As shown in FIG. 14, the radiations incident into the scintillator 120 are converted to light rays mostly in an incident or irradiated side of the scintillator 120. Of these light rays, relatively refrangible short wavelength components 122a will be fully reflected inside the columnar crystal 121a and conducted along the columnar crystal 121a toward the reflector layer 124. Even if the incident angle of the short wavelength components 122a to the reflector layer 124 gets less than the critical angle and hence the short wavelength components 122a transfer from the columnar crystal 121a to the adjacent columnar crystal 121b, the short wavelength components 122a tend to be so refracted that the incident angle of the short wavelength components 122a inside the columnar crystal 121b becomes greater than the critical angle. Accordingly, incident positions of the short wavelength components 122a on the sensor panel 125 will not so greatly deviate from their originating positions in the scintillator 120.

In contrast to the short wavelength components 122a, less refrangible long wavelength components 122b of the generated light will deviate from their originating position, as shown in FIG. 15. For example, a long wavelength ray 122b generated in the irradiated area of a columnar crystal 121c of the scintillator 120 can travel across the columnar crystals before they reach the reflector layer 124. Even after reflected from the reflector layer 124, the long wavelength light ray 122b will further deviate from the origin while it is traveling toward the sensor panel 125. As a result, the long wavelength ray 122b of the light generated in the columnar crystal 121c will fall on the sensor panel 125 at a position corresponding to a columnar crystal 121d that is far from the columnar crystal 121c.

Indirect-conversion type radiation detectors include ISS (Irradiation Side Sampling) type and PSS (Penetration Side Sampling) type. The ISS type radiation detector, as shown in FIG. 14, includes a sensor panel 125, a scintillator 120 and a reflector layer 124 arranged in this order from the irradiated side so that radioactive rays penetrating the sensor panel 125 are converted to light by the scintillator 120 and the sensor panel 125 detects the light. In the PSS type, which is not shown in the drawings though, a reflector layer, a scintillator and a sensor panel are arranged in this order from the irradiated side so that the scintillator converts radioactive rays that penetrate the reflector layer. In the PSS type detector, the light generated in the irradiated area of the scintillator will be immediately reflected from the reflector layer to the sensor panel as the reflector layer is located adjacent to the irradiated side. In the ISS type detector, the light generated in the irradiated area of the scintillator will be propagated inside the scintillator to the reflector layer, reflected from the reflector layer and then propagated again inside the scintillator to reach the sensor panel. Therefore, the distance of light propagation in the ISS type is substantially twice that in the PSS type. This will enhance the adverse effect of the crosstalk.

As a solution for the above problem, a retro-reflection layer is suggested as the reflector layer of the radiation detector, for example in U.S. patent application publication No. 2002/014592 (corresponding to JPA 2002-055168) and JPA 1997-090100. Because the retro-reflection layer reflects the incident light in the opposite direction to the incoming direction of the light, the reflected light, including irrefrangible long wavelength components, can reach the sensor panel at a position closer to its originating position inside the scintillator.

The retro-reflection layer may be fabricated with a large number of micro glass beads or micro prisms. In either type, depending upon the incident position or incident angle of light on the retro-reflection layer, the incident light may partly be absorbed or diffused without being retroreflected. For this reason, the retro-reflection layer is inferior in reflection efficiency to the specular reflection layer. Therefore, the retro-reflection layer used in the radiation detector may reduce the intensity or yield of light from the scintillator to the sensor panel and hence degrade the image quality of the radiographs.

### SUMMARY OF THE INVENTION

In view of the foregoing, an object of the present invention is to prevent the crosstalk of long wavelength components of light inside a scintillator of a radiation detector without lowering the reflection efficiency of a reflector layer of the radiation detector.

According to the present invention, a radiographic device includes a scintillator for converting incident radiations to light; a sensor panel having a photosensor for detecting the light obtained through the conversion of the incident radiations by the scintillator, the sensor panel being placed on a light emitting side of the scintillator; and a reflector layer placed on the opposite side of the scintillator to the light emitting side, the reflector layer being configured to selectively reflect the light from the scintillator toward the light emitting side either specularly or retroreflectively.

Preferably, the reflector layer reflects the light from the scintillator either specularly or retroreflectively depending on the wavelength of the light. More preferably, the reflector layer specularly reflects short-wavelength components of the light and retroreflects long-wavelength components of the light.

In one embodiment, the reflector layer includes a first reflective layer that specularly reflects the short-wavelength components of the light and lets the long-wavelength components of the light pass through it, and a second reflective layer that retroreflects the long-wavelength components of the light after passing through the first reflective layer. The first reflective layer may preferably be constructed as a dichroic filter.

Preferably, the first reflective layer and the second reflective layer are laminated such that a scintillator panel is disposed on one surface of the first reflective layer and the second reflective layer is disposed on the other surface of the first reflective layer.

The second reflective layer is preferably coated with retroreflective material containing glass beads. The second reflective layer preferably has numbers of micro prisms on its surface.

The radiographic device further includes a protective film covering up the scintillator panel, such that the first reflective layer is kept in tight contact with the scintillator panel by adhesive power of the protective film.

The first reflective layer is preferably bonded to the scintillator panel with a transparent adhesive. The first reflective layer is preferably bonded to the second reflective layer with a transparent adhesive.

In one embodiment, the sensor panel is placed on an irradiated side of the scintillator so that the radiations are incident into the scintillator after penetrating the sensor panel.

Preferably, the scintillator includes multiple columnar crystals oriented substantially vertically to the sensor panel. The scintillator may preferably be formed from thallium-doped cesium iodide.

Preferably, the scintillator includes multiple columnar crystals oriented substantially vertically to the sensor panel, and is formed from thallium-doped cesium iodide.

The sensor panel is preferably a CMOS sensor using an organic photoelectric conversion material.

In another aspect of the present invention, a radiographic device, which includes a scintillator for converting radiations to light and a sensor panel having a photosensor for detecting the light obtained through the conversion of the incident radiations by the scintillator, may be manufactured in the steps of forming the scintillator on one side of the sensor panel, and providing a reflector layer on the opposite side of the scintillator to the sensor panel, the reflector layer selectively reflecting the light from the scintillator either specularly or retroreflectively.

The radiographic device of the present invention may also be manufactured in the following steps: forming the scintillator on a light-permeable substrate; providing a reflector layer on the substrate such that the reflector layer selectively reflects the light from the scintillator either specularly or retroreflectively; and bonding the scintillator and the sensor panel together.

The reflector layer is preferably comprised of a first reflective layer that specularly reflects the short-wavelength components of the light and lets the long-wavelength components of the light pass through it, and a second reflective layer that retroreflects the long-wavelength components of the light after passing through the first reflective layer.

According to the present invention, among the light generated in the scintillator, relatively refrangible short-wavelength components, which are less likely to cause the crosstalk, may be selected to be specularly reflected toward the sensor panel, in order not to lower the intensity of light detected by the sensor panel. On the other hand, less refrangible long-wavelength components, which are more likely to cause the crosstalk, may be selected to be retroreflected toward the sensor panel. Thus, the adverse effect of the crosstalk of the long-wavelength components on the radiographic image may be effectively suppressed.

### BRIEF DESCRIPTION OF THE DRAWINGS

The above and other objects and advantages of the present invention will be more apparent from the following detailed description of the preferred embodiments when read in connection with the accompanied drawings, wherein like reference numerals designate like or corresponding parts throughout the several views, and wherein:

FIG. 1 is a partially cutaway perspective view illustrating a radiographic device;

FIG. 2 is a schematic sectional view of the radiographic device;

FIG. 3 is a fragmentary sectional view of a marginal portion of a radiation detector;

FIG. 4 is a graph showing a light emission property of thallium-doped cesium iodide;

FIG. 5 is a graph showing a light emission property of sodium-activated cesium iodide;

FIG. 6 is a fragmentary sectional view of the radiographic device, illustrating a schematic structure of a photosensor;

FIG. 7 is a block diagram illustrating essential electric components of the radiographic device;

FIG. 8 is a block diagram illustrating essential electric components of a console and a radiation generator;

FIG. 9 is an explanatory diagram illustrating light paths of short-wavelength components and long-wavelength components as reflected from a reflector layer in accordance with the present invention;

FIG. 10 is an explanatory diagram illustrating a light path of long-wavelength light generated in the scintillator at a position closer to the reflector layer;

FIG. 11 schematically illustrates a procedure of fabricating the scintillator and the reflector layer;

FIG. 12 schematically illustrates another procedure of fabricating the scintillator and the reflector layer;

FIG. 13 is an explanatory diagram illustrating light paths in a conventional scintillator when a crosstalk occurs;

FIG. 14 is an explanatory diagram illustrating a light path of short-wavelength light as reflected from a specular reflector layer in a conventional radiation detector; and

FIG. 15 is an explanatory diagram illustrating a light path of long-wavelength light as reflected from the specular reflector layer in the conventional radiation detector.

### DESCRIPTION OF THE PREFERRED EMBODIMENTS

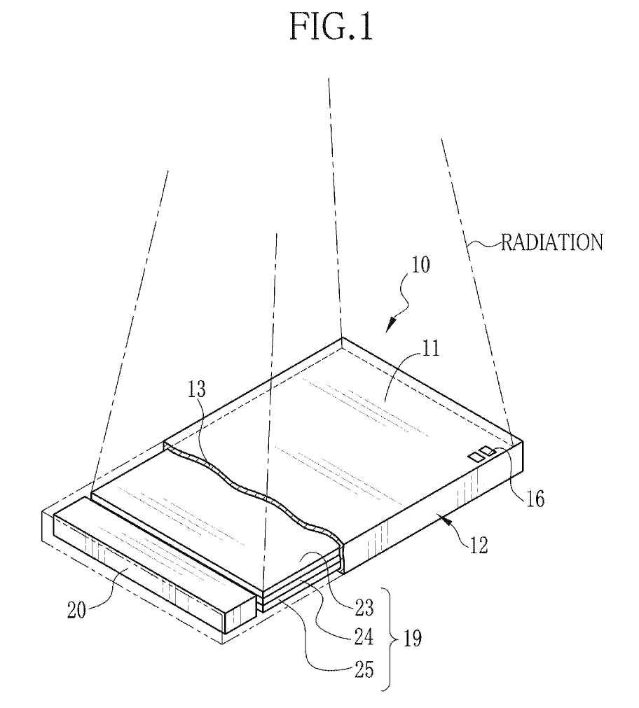

As shown in FIG. 1, a radiographic device 10 in accordance with the present invention has a housing 12 that is substantially box-shaped as the whole and has a rectangular irradiation surface 11 on its top side. The housing 12 is made of a radiolucent material. For example, a top wall 13 with the irradiation surface 11 is made of carbon, and other walls are made of ABS resin. This will suppress absorption of the radiation into the top plate 13 and ensure the strength of the top plate 13 as well. The housing 12 may have the same size as conventional radiographic cassettes that are configured to record an image on a radiation-sensitive material, so that the radiographic device 10 may be substituted for the conventional cassette.

On the irradiation surface 11 of the radiographic device 10, a display section 16 is provided for displaying the present operating condition of the radiographic device 10, such as the present operation mode, e.g. “ready”, “data transmitting” or the like, and the remaining battery level. The display section 16 may be constituted of multiple LEDs or other light emitting elements, or may also be a liquid crystal display or an organic light emitting display (OLED). The display section 16 may be provided on other portion of the housing 12 than the irradiation surface 11.

Inside the housing 12 of the radiographic device 10, a panel-shaped radiation detector 19 is disposed in opposition to the irradiation surface 11 so as to detect radiations that have penetrated the body of a subject. In addition, a case 20 containing a variety of electronic circuits, including that for a microcomputer, and rechargeable reloadable batteries (secondary electric cells) is disposed in a marginal place inside the housing 12, extending in the widthwise direction of the irradiation surface 11. The electronic circuits of the radiographic device 10, including that of the radiation detector 19, are actuated by electric power supplied from the batteries in the case 20. A not-shown radiation shielding member, which may for example be a lead sheet, is provided in between the case 20 and the top plate 13, for shielding the electronic circuits in the case 20 from being damaged by the radiations.

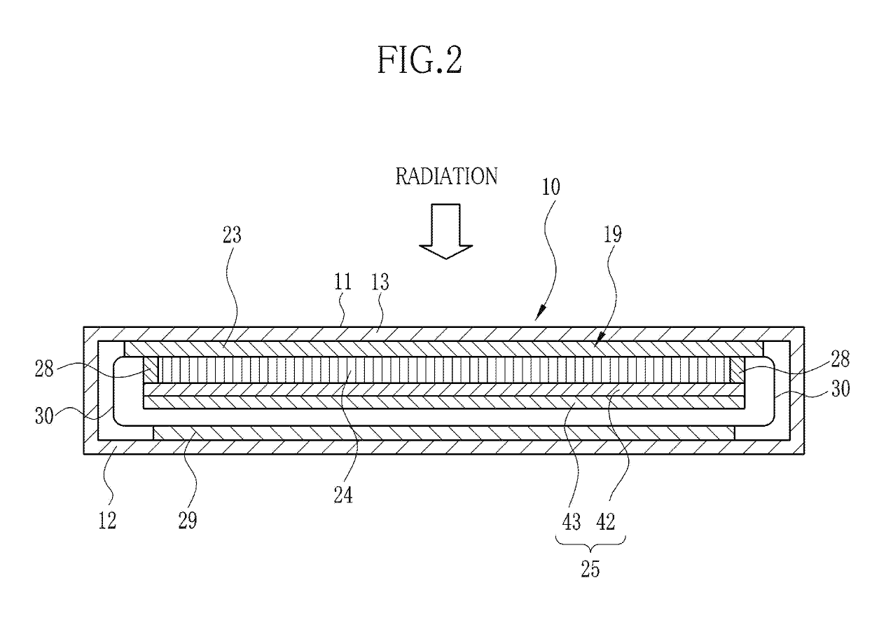

The radiation detector 19 is structured by laminating a sensor panel 23, a scintillator panel 24 and a reflector layer 25 in this order from the side of the irradiation surface 11, i.e. from the top side of the radiographic device 10. As shown in FIG. 2, the sensor panel 23 is adhered to the entire internal surface of the top plate 13. The scintillator panel 24 is provided directly underneath the sensor panel 23, and the reflector layer 25 is provided directly underneath the scintillator panel 24. A sealing material 28 is provided around the periphery of the scintillator panel 24, to shield the scintillator panel 24 from moisture and other extraneous substances. A control circuit board 29 is mounted on the internal bottom surface of the housing 12. The control circuit board 29 and the sensor panel 23 are electrically interconnected through a flexible cable 30.

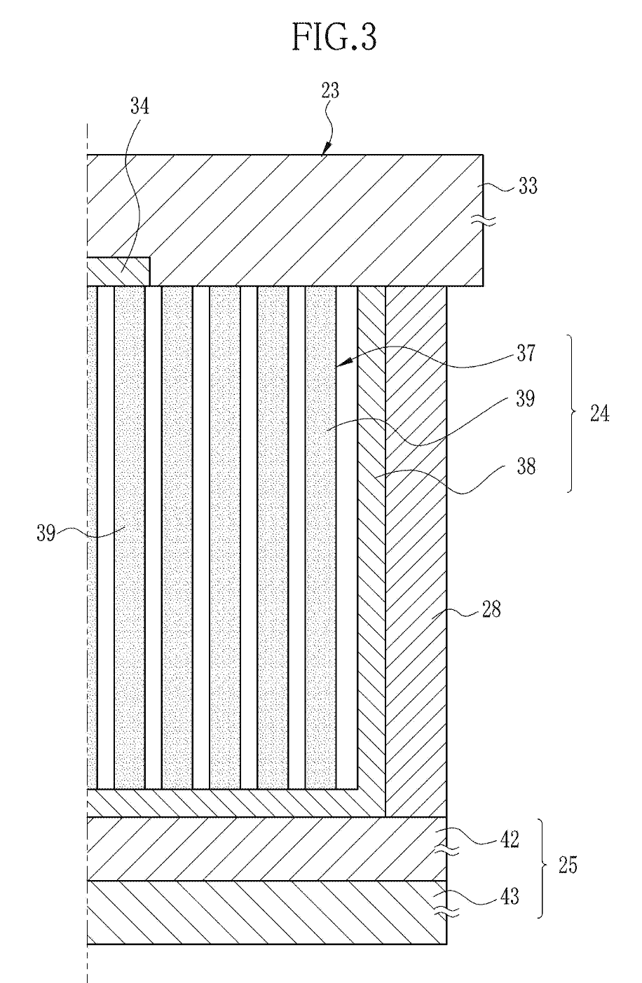

Referring to FIG. 3, the radiation detector 19 is illustrated in more detail. The sensor panel 23 for detecting light from the scintillator panel 24 includes a planer sensor substrate 33 with a rectangular top plane and a photosensor 34 mounted in the bottom of the sensor substrate 33. The photosensor 34 may consist of photo diodes, and the sensor substrate 33 may preferably be a heat-resistant glass substrate, which is suitable for forming the photo diodes by vapor deposition of amorphous silicon. The sensor substrate 33 may have a thickness of about 700 μm.

The scintillator panel 24 consists of a scintillator 37 vapor-deposited on the sensor substrate 33 and a protective film 38 covering up the periphery of the scintillator 37. The radiations, which have penetrated the body of the subject and are incident on the irradiated side 11 of the housing 12, will penetrate the top plate 13 and the sensor panel 23 and reach the scintillator 37. Then the scintillator 37 absorbs the radiations and emits light. Generally, the scintillator 37 may be made of CsI(Tl) (thallium-doped cesium iodide), CsI(Na) (sodium-activated cesium iodide), or GOS (Gd₂O₂S:Tb). In the present embodiment, the scintillator 37 is fabricated by vapor-depositing CsI(Tl) on the sensor substrate 33, forming numbers of columnar crystals 39 that extend in the light exiting direction from the scintillator 37 to the sensor panel 23. The columnar crystals 39 have an approximately equal average diameter throughout their length.

The light generated by the scintillator 37 is directed by the light guiding effect of the columnar crystals 39 toward the sensor panel 23. The columnar crystals 39 suppress diffusion of the light during the propagation toward the sensor panel 23, which contributes to suppressing degrading of the spatial resolution of radiographs acquired by the radiographic device 10. The light generated in the scintillator 37 will also propagate toward the reflector layer 25 and is reflected toward the sensor panel 23, increasing the intensity of light, i.e. the yield of light generated in the scintillator 37 and detected by the sensor panel 23.

When fabricating the scintillator 37, CsI should be filled at an appropriate rate, which depends on the thickness of the scintillator 37 but may preferably be set in a range of 70-88%. If the filling rate of CsI is too low (e.g. less than 70%), the intensity of light generated by the scintillator 37 will remarkably decrease. If the filling rate of CsI is too high (e.g. more than 85%), adjacent columnar crystals will get into contact with each other above a certain thickness. The contact between the columnar crystals causes the crosstalk of the generated light. The crosstalk will change the pattern or intensity distribution of light detected by the sensor panel 23 from the original pattern of irradiance on the scintillator 37, resulting in worsening the accuracy of radiation detection and the sharpness or special resolution of the radiographic image detected by the radiographic device 10. Therefore, in order to ensure adequate sensitivity and accuracy of detection to the radiation, it is necessary to space the adjacent columnar crystals from each other at appropriate intervals.

The protective film 38 is made of a material with barrier properties against atmospheric moisture. The protective film 38 may for example be an organic film produced by vapor phase polymerization such as heat CVD (chemical vapor deposition) method or plasma CVD method. The available organic film includes vapor phase polymerized film produced by the heat CVD of polyparaxylylene resin, plasma polymerized film of fluorine-containing compound of unsaturated hydrocarbon monomer, or plasma polymerized film of unsaturated hydrocarbon monomer. In addition, a laminated structure of an organic film and an inorganic film may be available for the protective film 38. For example, silicon nitride (SiNx) film, silicon oxide (SiOx) film, acid silicon nitride (SiOxNy) film, and Al₂O₃ are suitable for the material of the inorganic film.

In the present embodiment, the sensor panel 23 is disposed on the irradiated or incident side of the scintillator panel 24. The radiation detector adopting this arrangement of the scintillator and the sensor panel is called ISS (Irradiation Side Sampling) type. On the other hand, PSS (Penetration Side Sampling) type radiation detector has the photosensor on the opposite side from the irradiated side. Because the scintillator emits light with greater intensity on the irradiated side, the ISS type radiation detector, placing the photosensor closer to the light emitting position inside the scintillator than the PSS type, can achieve higher resolution of the acquired radiographic images, and improved sensitivity to radiation due to increased light intensity on the photosensor.

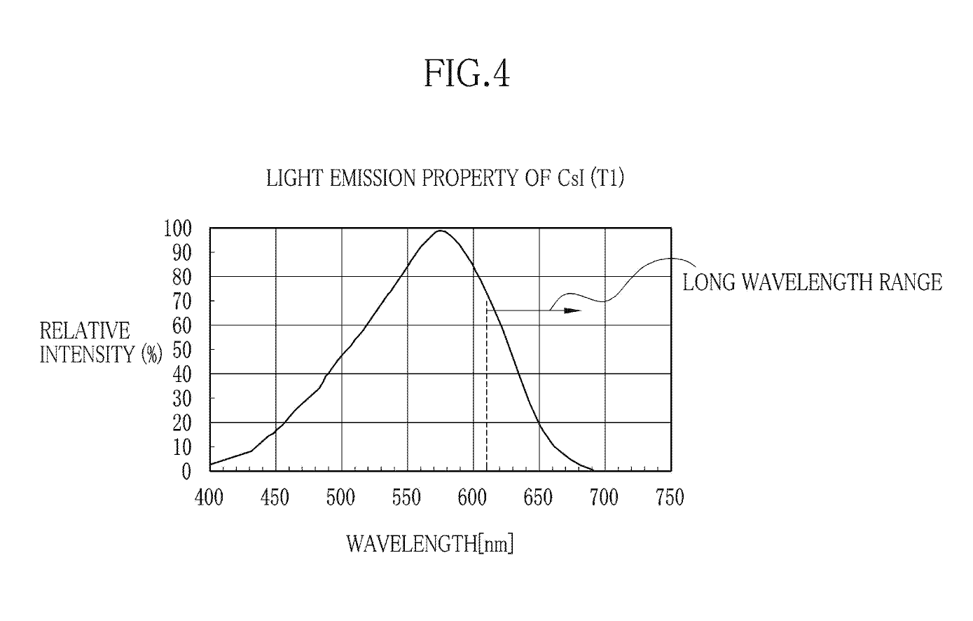

The reflector layer 25 consists of a first reflective layer 42 provided tightly on the bottom of the scintillator panel 24 and a second reflective layer 43 bonded to the bottom of the first reflective layer 42. The first reflective layer 42 is constructed as a dielectric filter that is transparent to long wavelength light components but specularly reflects short wavelength light components. As shown in FIG. 4, light generated from CsI(Tl) has its luminescence peak at 565 nm but covers a wide spectral range of from approximately 400 nm to 700 nm. In the present embodiment, the dielectric filter is configured to be transparent to light components having longer wavelengths than 565 nm, the luminescence peak wavelength of the scintillator 37, e.g. in a wavelength range over 620 nm or 630 nm.

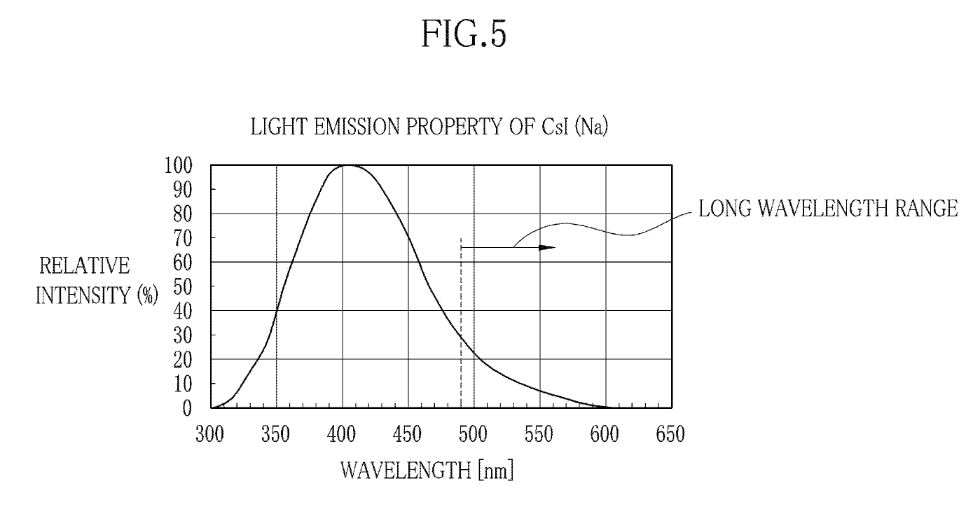

In an embodiment where the scintillator 37 is produced using CsI(Na), which emits light with a spectral curve as shown in FIG. 5, the first reflective layer 42 may be configured to let pass those light components having longer wavelengths than 400 nm, the luminescence peak wavelength of CsI(Na), e.g. in a wavelength range over 480 nm. The first reflective layer 42 specularly reflects light components under this long wavelength range.

The second reflective layer 43 is constructed as a retro-reflection layer, which retro-reflects the long wavelength light components, which have passed through the first reflective layer 42. That is, the second reflective layer 43 reflects the incident light in the direction reverse to the incoming direction of the light rays. The retro-reflection layer for the second reflective layer 43 may for example be a retroreflective plate coated with retroreflective material containing micro glass beads, or a retroreflective plate with numbers of micro prisms on its surface.

The first reflective layer 42 is kept in tight contact with the scintillator panel 24 by adhesive power of the protective film 38 after the scintillator 37 is deposited on the sensor panel 23 and covered with the protective film 38. Alternatively, the first reflective layer 42 and the scintillator panel 24 may be bonded together with a highly transparent adhesive. The second reflective layer 43 may be bonded to the first reflective layer 42 with a highly transparent adhesive.

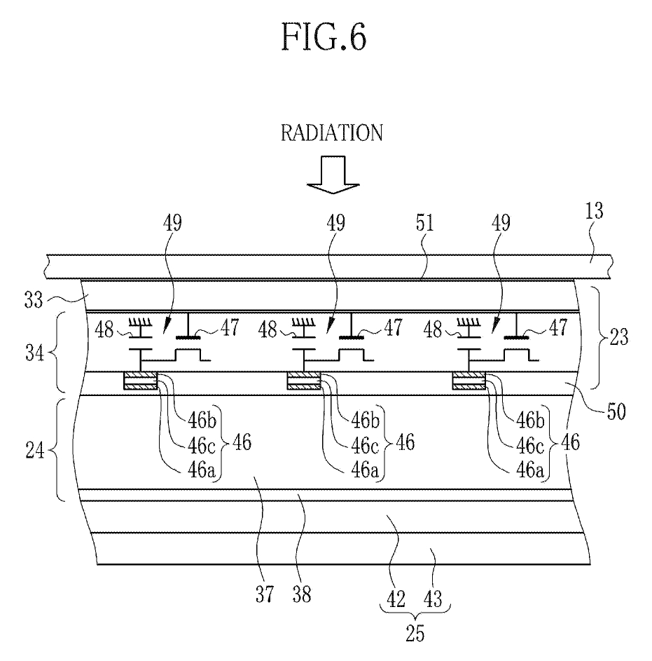

Next the sensor panel 23 will be described in detail. As shown in FIG. 6, the photosensor 34 of the sensor panel 23 includes a lot of sensor pixels 49, which are arranged in a matrix on the sensor substrate 33, each sensor pixel 49 including a photoelectric convertor 46, which may be a photodiode, a thin film transistor (TFT) 47 and a charge capacitor 48. A smoothing layer 50 is provided on the opposite surface of the sensor panel 23 to the sensor substrate 33, for smoothing the opposite surface. As described above, the sensor panel 23 is adhered to the top plate 13 through an adhesive layer 51.

The photoelectric convertor 46 is structured by sandwiching a photoelectric conversion film 46c between a pair of electrodes 46a and 46b. The photoelectric conversion film 46c absorbs light from the scintillator 37 and generates electric charges corresponding to the absorbed light. The lower electrode 46a is preferably made of a conductive material that is transparent at least to light of the luminescent wavelength range of the scintillator 37, because the light from the scintillator 37 should be transmitted to the photoelectric conversion film 46c. Specifically, as the material for the lower electrode 46a, transparent conductive oxide is preferable because of its high transmittance to visible light and low electrical resistance.

Metal thin film, such as gold thin film, may also be used for the lower electrode 46a, but transparent conductive oxides (TCO) are more preferable. This is because the resistance of the metal thin film tends to increase in order to achieve a high optical transmittance of 90% or more. For example, ITO (indium-doped tin oxide), IZO (indium-dope zinc oxide), AZO (aluminum-doped zinc oxide), FTO (fluorine-doped tin oxide), SnO₂, TiO₂ and ZnO₂ may be preferably used for the lower electrode 46a, and ITO is the most preferable in view of its processability, low-resistance and transparency. The lower electrode 46a may be constructed as a common electrode to all pixels, or a separate electrode for each individual pixel.

The photoelectric conversion film 46c may be made of any material insofar as it absorbs light and converts the light into electric charges. For example, amorphous silicon or an organic photoelectric conversion material is applicable. The photoelectric conversion film 46c, made of amorphous silicon, can absorb light from the scintillator 37 in a wide wavelength range. Because vapor deposition is necessary for forming the photoelectric conversion film 46c of amorphous silicon, the sensor substrate 33 should preferably be a heat-resistant glass substrate in that case.

In each thin film transistor (TFT) 47, a gate electrode, a gate insulating film and an active layer (channel layer) are formed atop another, and a source electrode and a drain electrode are formed on the active layer with a predetermined distance therebetween. The active layer may for example be formed of any of amorphous silicon, amorphous oxides, organic semiconductor materials and carbon nanotubes, but the material for the active layer is not limited to these.

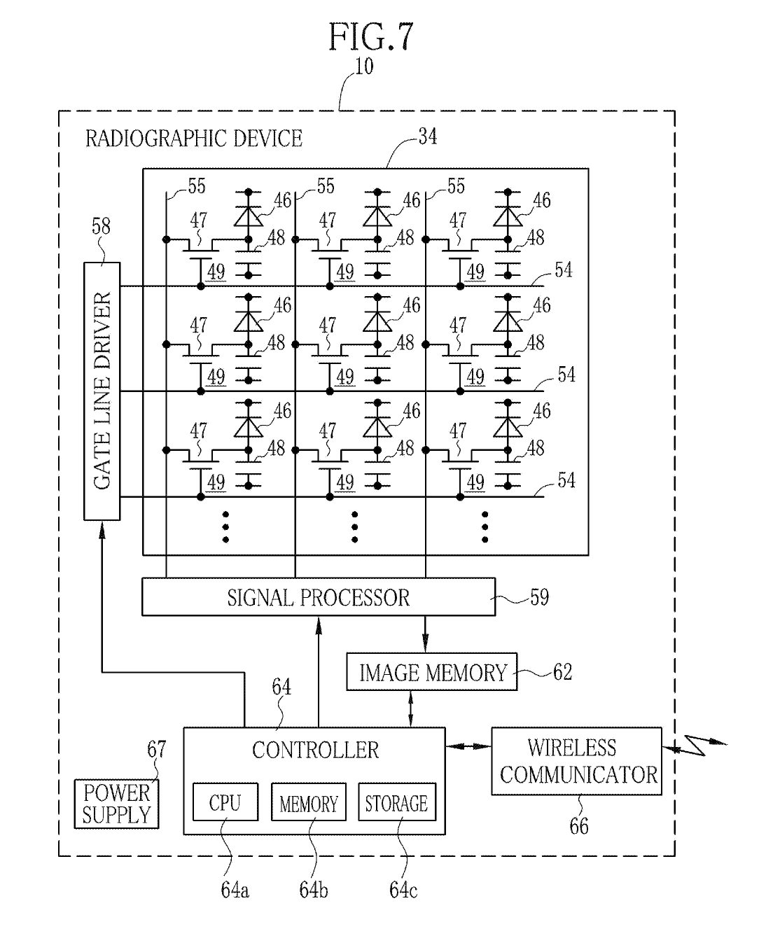

In the photosensor 34, as shown in FIG. 7, multiple gate lines 54 for conducting signals for switching the TFTs 47 on and off are provided in parallel to a line direction of the pixel matrix, and multiple data lines 55 are provided in parallel to a column direction of the pixel matrix, that is orthogonal to the line direction. Through the data lines 55, charges accumulated in each charge capacitor 48 (and also in between the electrodes 46a and 46b of each photoelectric converter 46) may be read out when the individual TFT 47 is ON.

The gate lines 54 are connected to a gate line driver 58, whereas the data lines 55 are connected to a signal processor 59. When the radiographic device 10 is irradiated with radiations, which have penetrated through the subject body and hence carry graphic information on the subject body, the scintillator 37 emits a light ray from each point corresponding to an incident point of a radioactive ray on the irradiation surface 11 at a luminance corresponding to a radiance of the incident radioactive ray. Then the photoelectric convertor 46 of each sensor pixel 49 generates an electric charge of an amount corresponding to the luminance of the light ray emitted from the corresponding point of the scintillator 37. The electric charge generated by the photoelectric convertor 46 is accumulated in the charge capacitor 48 of the individual sensor pixel 49 (and in the gap between the lower and upper electrodes 46a and 46b of the photoelectric convertor 46).

After the charge capacitor 48 of each sensor pixel 49 accumulates the electric charges, the TFTs 47 of the sensor pixels 49 are line-sequentially turned on by signals applied through one gate line 54 after another from the gate line driver 58. While the TFTs 47 of the sensor pixels 49 of one line are ON, the electric charges accumulated in the charge capacitors 48 of these sensor pixels 49 are transmitted as analog electric signals through the data lines 55 to the signal processor 59. Thus the electric charges are read out from the charge capacitors 48 in a line-sequential fashion.

The signal processor 59 includes amplifiers and sample-and-hold circuits in connection to the respective data lines 55, so that the electric signal transmitted through each data line 55 is amplified and then held in the sample-and-hold circuit. Outputs of the sample-and-hold circuits are connected to a multiplexer, and an analog-to-digital (A/D) convertor is connected to an output of the multiplexer. The electric signals held in the respective sample-and-hold circuits are sequentially (serially) fed to the multiplexer, and then converted to digital image data through the A/D converter.

An image memory 62 is connected to the signal processor 59, so that the image data output from the A/D converter of the signal processor 59 is stored in the image memory 62. The image memory 62 is capable of storing more than one frame of the image data, and stores the image data sequentially upon each radiographic acquisition.

The image memory 62 is connected to a controller 64 that controls the overall operation of the radiographic device 10. The controller 64 includes a microcomputer provided with a CPU 64a, a memory 64b, including ROM and RAM, and a non-volatile storage device 64c such as a hard disk drive (HDD), a flash memory and the like.

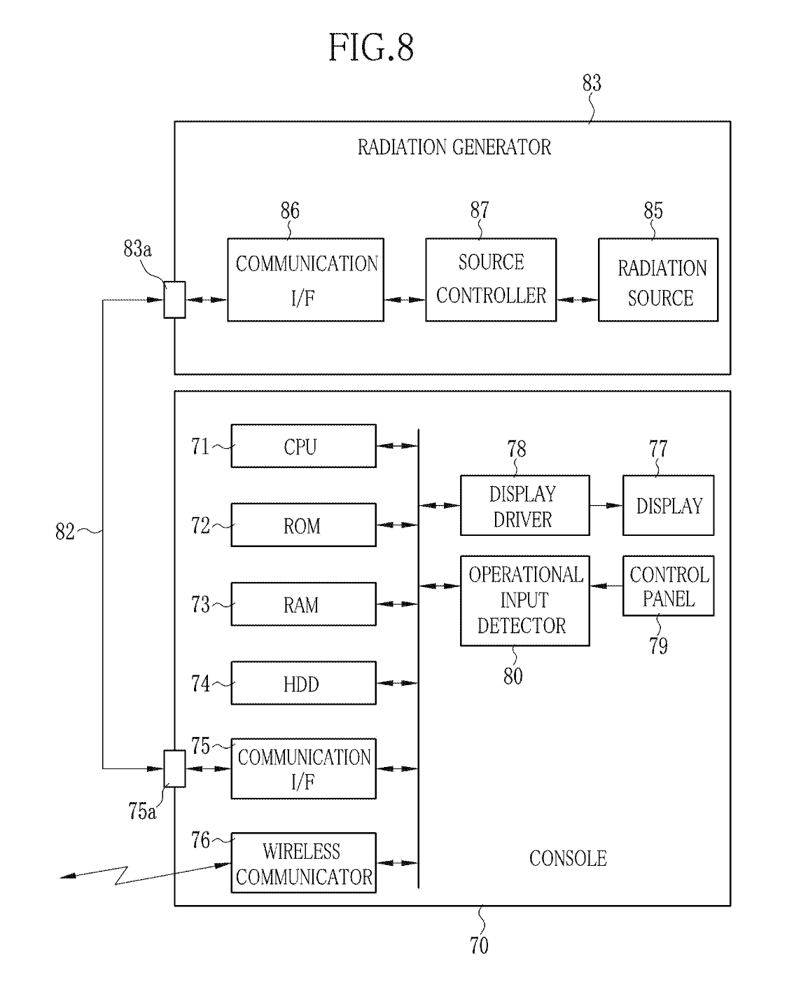

The controller 64 is also connected to a wireless communicator 66. The wireless communicator 66 is compatible to wireless LAN standards, like IEEE 802.11a/b/g/n, and controls wireless transmission of various data with peripheral equipment. Through the wireless communicator 66, the controller 64 can wirelessly communicate with a console 70 (see FIG. 8) to send and receive various data to and from the console 70.

In addition, the radiographic device 10 is provided with a power supply 67, and the above described various electronic circuits, including the gate line driver 58, the signal processor 59, the image memory 62, the controller 64 and the wireless communicator 66, are respectively connected to the power supply 67 and power-supplied from the power supply 67. The power supply 67 includes the above described rechargeable batteries (the secondary cells) for making the radiographic device 10 portable. Thus the power supply 67 supplies power from the charged batteries to the electronic circuits. The gate line driver 58, the signal processor 59, the image memory 62, the controller 64, the wireless communicator 66 and the power supply 67 are provided in the case 20 or on the control circuit board 29.

As shown in FIG. 8, the console 70 consists of a computer, which includes CPU 71 for controlling the overall operation of the apparatus, ROM 72 previously storing various programs and other data, including a control program, RAM 73 for temporary storage of various data, and HDD 74 for storage of various data, these components being interconnected through a bus. The bus also connects to a communication interface (I/F) 75, a wireless communicator 76, a display 77 via a display driver 778, and a control panel 79 via an operational input detector 80.

The communication interface 75 is connected to a radiation generator 83 via a communication cable 82 connected between a contact terminal 75a of the console 70 and a contact terminal 83a of the radiation generator 83. The console 70, specifically the CPU 71 of the console 70, exchanges various data, including dose condition settings, with the radiation generator 83 via the communication interface 75. The wireless communicator 76 has a function of wireless communication with the wireless communicator 66 of the radiographic device 10, so that the console 70 (the CPU 71) may exchange various data, including image data, with the radiographic device 10 via the wireless communicator 76. The display driver 78 generates and output signals to the display 77 for displaying various information. The console 70 (the CPU 71) controls the display driver 78 to display operation menus or acquired radiographic images on the display 77. The control panel includes various keys for inputting various data and operational commands. The operational input detector 80 detects the operations on the control panel 79, and sends the detection results to the CPU 71.

The radiation generator 83 includes a radiation source 85, a communication interface 86 for communication with the console 70, and a radiation source controller 87 for controlling the radiation source 85 on the basis of the dose condition settings, including information on tube voltage and tube current, received from the console 70 via the communication interface 86.

Now the operation of the present embodiment will be described. To acquire a radiographic image from a subject by the radiographic device 10, a person in charge of radiography (e.g. a radiologist) inserts the radiographic device 10 into between a target site of the subject and a radiographic table with the irradiated side 11 of the radiographic device 10 upward, while adjusting the position or orientation of the radiographic device 10.

After positioning the radiographic device 10, the person in charge enters a start command by operating the control panel 79. Then the console 70 sends a radiation start signal to the radiation generator 83, upon which the radiation generator 83 activates the radiation source 85 to emit radiations. The radiations from the radiation source 85 penetrate through the subject body and get to the irradiation surface 11 of the radiographic device 10. Then the radiations pass through the top plate 13 and the sensor panel 23 to an irradiated/light emitting surface of the scintillator 37. The scintillator 37 absorbs the radiations incident on the irradiated/light emitting surface, and emits light rays corresponding to the absorbed radiations.

The sensor panel 23 detects the light incident into the sensor pixels 49 and the detected light is stored as image data of the subject in the image memory 62. The CPU 64a transmits the stored image data to the console 70 through the wireless communicator 66. The CPU 71 of the console 70 stores the image data received from the radiographic device 10 temporarily in the RAM 73 and then in the HDD 74. The CPU 71 controls the display driver 78 to display a radiographic image on the display 77 using the image data.

As described above with reference to FIG. 15, long-wavelength components 122b of light generated in an area of the scintillator 120 near the irradiated side tend to pass through the columnar crystals 121 as they are transmitted from the origin toward the reflector layer 124 because of the irrefrangibility of the long-wavelength components 122b. Where the reflector layer 124 is constructed as a specular reflection layer, the long-wavelength components 122b will deviate farther from the origin after being reflected from the reflector layer 124 to the sensor panel 125. The deviation of the incident position of light on the sensor panel from its originating position in the scintillator will result in blurring of the acquired radiographic image. An existing radiation detector using a retro-reflection layer, however, has a program in that the retro-reflection layer is inferior in reflection efficiency to the specular reflection layer so that the light from the scintillator is reduced in intensity as detected by the sensor panel. Reduced intensity of incident light on the sensor panel will degrade the image quality of the radiographs.

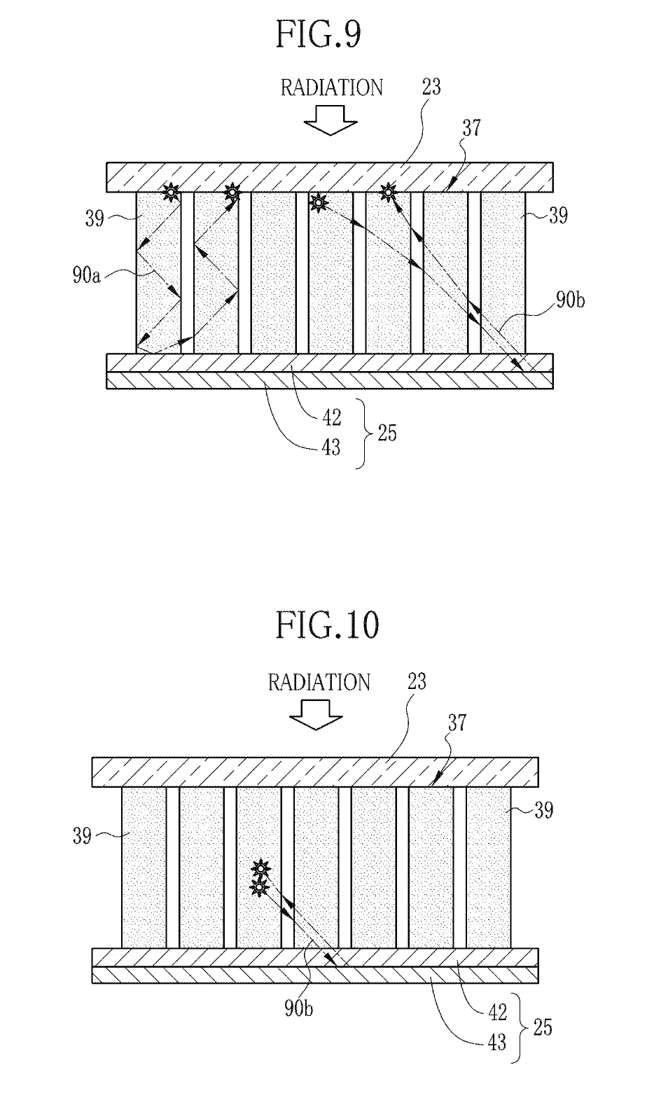

In contrast, the radiation detector 19 of the present embodiment is configured such that the first reflector layer 42 specularly reflects short-wavelength components 90a of the light generated in the scintillator 37, as shown in FIG. 9, achieving reflection efficiency or high yield of light and thus preventing lowering the luminance of light detected by the sensor panel 23. Because the short-wavelength components 90a are relatively refrangible, and their incident angles to the columnar crystals 39 tend to be greater than the critical angle, the short-wavelength components 90a can reach the sensor panel 23 at a position near the origin in the scintillator 37 even after being specularly reflected. Therefore, specular reflection of the short-wavelength components 90a is effective to prevent degrading the image resolution.

Less refrangible long-wavelength components 90b of the light, which tend to deviate from the origin in the scintillator 37 during propagation to the reflector layer 25, will pass through the first reflective layer 42 and then be retroreflected from the second reflective layer 43, so that the long-wavelength components 90b can fall on the sensor panel 23 at a position near the origin. Thus retro-reflection of the long-wavelength components 90b prevents blurring that can be caused by the crosstalk of the long-wavelength components 90b. As described so far, according to the present invention, specular reflection and retro-reflection are selectively applied to the generated light depending on the wavelength range so as to get the best of both reflective layers while preventing adverse effects of the specular reflection and the retro-reflection on the image detection. Thus the quality of the acquired radiographic image is improved.

The radiation incident into the scintillator 37 may be converted to light in a position nearer to the reflector layer 25. In the conventional radiation detector, as shown in FIG. 15, even when the light is generated in the vicinity of the reflector layer 25, the long-wavelength components 122b will deviate from the origin as they are reflected from the reflector layer 124 toward the sensor panel 125. In the present embodiment, on the other hand, the long-wavelength components 90b will be retroreflected by the second reflective layer 43 after passing through the first reflective layer 42 and hence returned to a position near the origin, as shown for example in FIG. 10.

In the above embodiment, specular reflection and retro-reflection are selectively applied to the light generated in the scintillator 37 depending on its wavelength range. In an alternative, selection between specular reflection and retro-reflection may be done depending on the incident angle of the generated light to the reflection layer. In this alternative, the first specular reflection layer may preferably be configured to reflect the light having an incident angle of not less than the critical angle of the columnar crystal, and let pass the light having an incident angle of less than the critical angle, while the light having an incident angle of less than the critical angle may preferably be retroreflected by the second retro-reflection layer. The same effect may be achieved by this configuration.

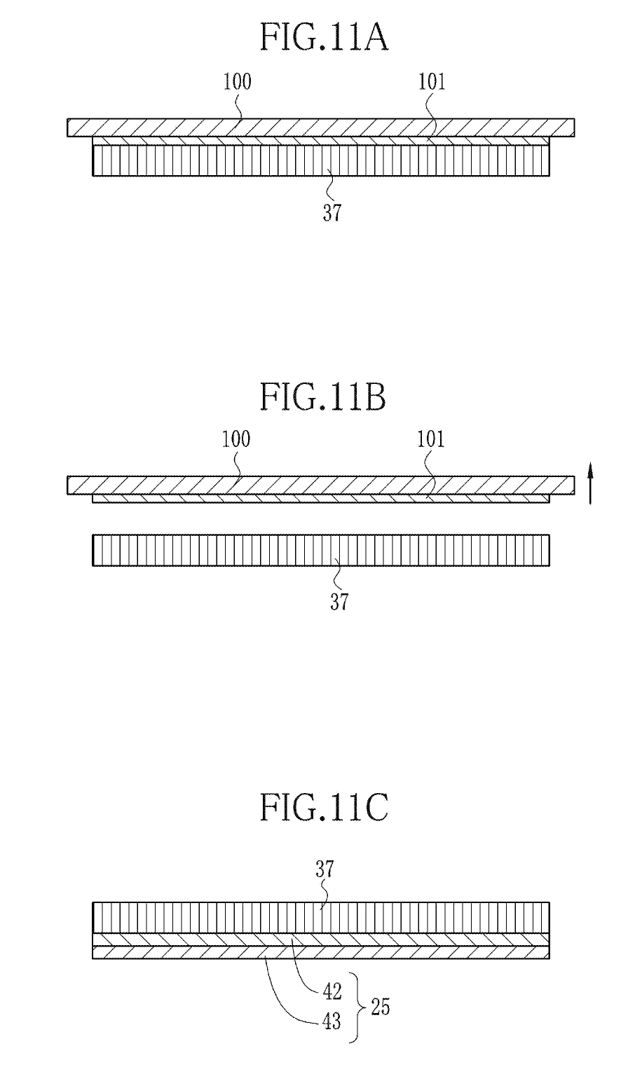

In the above embodiment, the scintillator 37 is directly deposited on the sensor panel 23. Alternatively, the scintillator 37 may be deposited on a substrate so that the scintillator 37 and the sensor panel 23 may be thereafter bonded together. For example, as shown in FIG. 11A, the scintillator 37 may be deposited on a peel ply 101 that is provided on a substrate 100 such as an aluminum plate, so that the scintillator 37 may be separated from the peel ply 101 and the substrate 100, as shown in FIG. 11B. Then the reflector layer 25 may be tightly stuck to the scintillator 37.

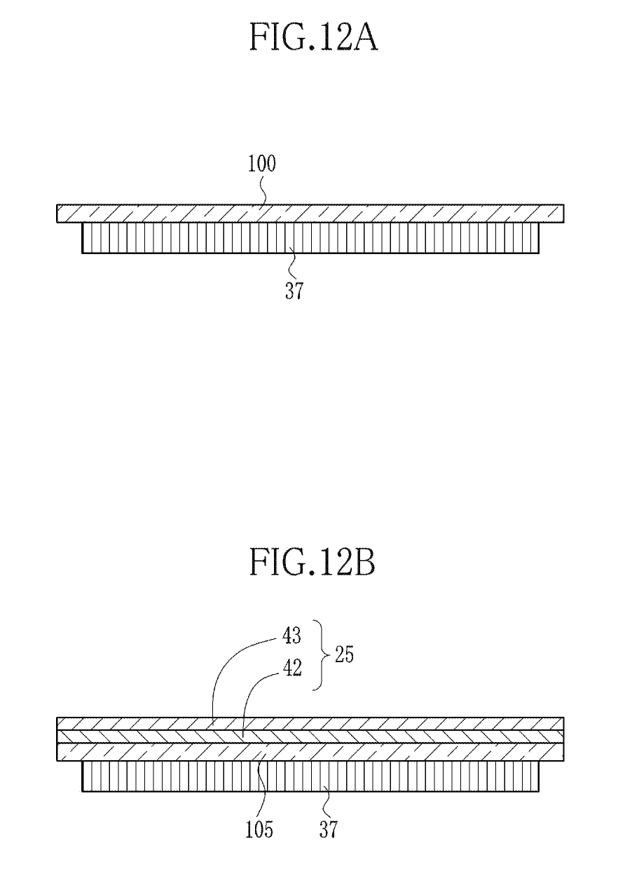

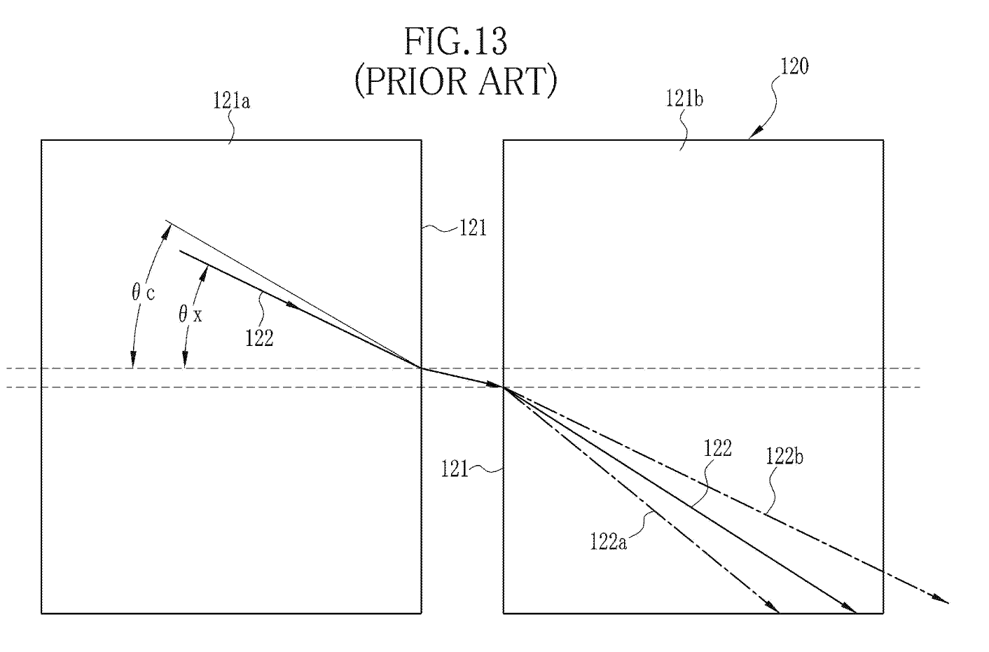

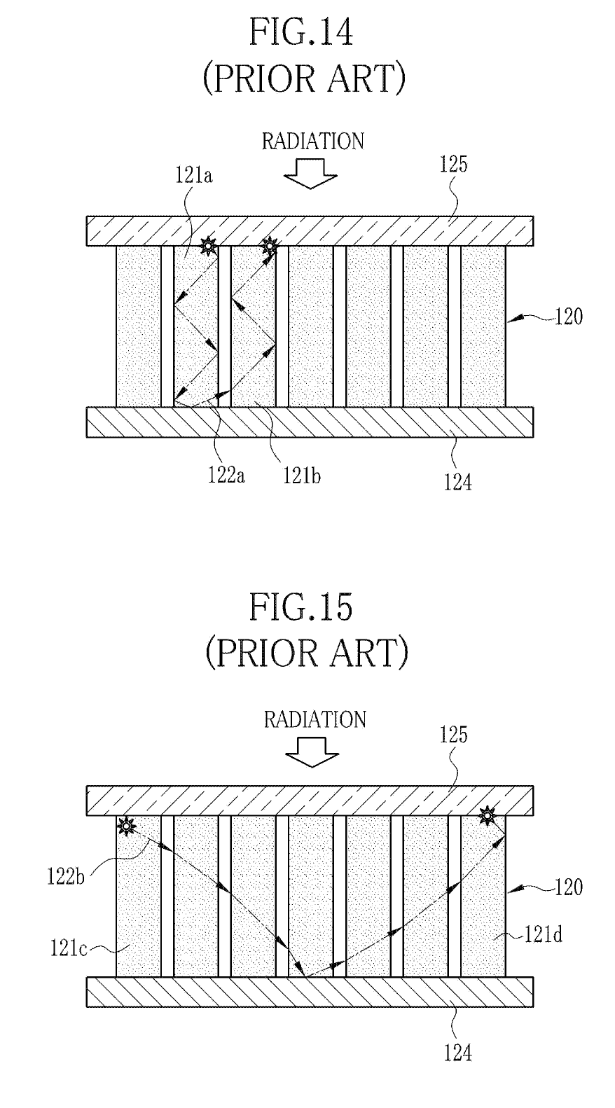

In another embodiment, as shown in FIG. 12A, the scintillator 37 may be deposited on one side of a substrate 105 that is made from a light-permeable heat-resistant resin. Then the reflector layer 25 may be formed on or adhered to the other side of the substrate 105. As the resin material for the substrate 105, transparent polyimide, polyarylate (PAR), biaxially-oriented polystyrene sheet, aramid are applicable.

In the first embodiment, the photoelectric conversion film 46c of the photoelectric converter 46 is formed from amorphous silicon. In another embodiment, an organic photoelectric conversion material may also be used for forming the photoelectric conversion film 46c. Then the photoelectric conversion film 46c can get such an absorption spectrum that shows high absorbance mainly in the range of visible light, and will hardly absorb electromagnetic waves other than the light emitted from the scintillator 37. Therefore, forming the photoelectric conversion film 46c from an organic photoelectric conversion material is effective to suppress noises that would be caused if the photoelectric conversion film 46c absorbs radiations like x-rays and y-rays. Moreover, the photoelectric conversion film 46c can be formed from an organic photoelectric conversion material by spraying the photoelectric conversion material onto the sensor substrate 33 using a nozzle head like an ink-jet head. In that case, the sensor substrate 33 needs not to be so heat-resistant that it may be made of less heat-resistant material than glass.

The photoelectric conversion film 46c, which is formed from organic photoelectric conversion material, will hardly absorb radiations. That is, attenuation of radiations through the sensor panel 23 is suppressed in the ISS type radiation detector where the sensor panel 23 is situated on the irradiation side and the scintillator converts radiations after passing through the sensor panel 23 to light. Thus, forming the photoelectric conversion film 46c from an organic photoelectric conversion material is preferable especially for the ISS type radiation detector in view of the sensitivity to radiations.

The organic photoelectric conversion material for the photoelectric conversion film 46c preferably has an as close absorption peak wavelength as possible to the emission peak wavelength of the scintillator 37 to the radiation, so that the photoelectric conversion film 46c can most efficiently absorb light emitted from the scintillator 37. Ideally, the absorption peak wavelength of the organic photoelectric conversion material coincides with the emission peak wavelength of the scintillator 37, but if the difference therebetween is small enough, light emitted from the scintillator 37 may be sufficiently absorbed into the photoelectric conversion film. Specifically, the difference between the absorption peak wavelength of the organic photoelectric conversion material and the emission peak wavelength of the scintillator 37 to the radiation is preferably 10 nm or less, and more preferably 5 nm or less.

As such organic photoelectric conversion material that can satisfy the above condition, quinacridone-based organic compounds and phthalocyanine-based organic compounds may be cited. Since the absorption peak wavelength of quinacridone is 560 nm in the range of visible light, quinacridone is preferably used as a material of the photoelectric conversion film 46c when the scintillator 37 is fabricated from CsI (Tl). Then the difference between these peak wavelengths may decrease to 5 nm or less, increasing the yield of electric charges generated in the photoelectric conversion film 46c substantially to the maximum.

The photoelectric conversion film 46c applicable to the radiation detector panel will be more specifically described.

An electromagnetic wave absorbing and photoelectric converting site in the radiation detector panel is constructed as organic layers including a pair of electrodes 46a and 46b and an organic photoelectric conversion film 46c sandwiched between the electrodes 46a and 46b. The organic layers may be formed, more specifically, by stacking or mixing an electromagnetic wave absorbing site, a photoelectric conversion site, an electron transporting site, a hole transporting site, an electron-blocking site, a hole-blocking site, a crystallization inhibition site, the electrodes, an interlayer contact improvement site and so on.

The above organic layers preferably include an organic p-type compound or an organic n-type compound. The organic p-type semiconductor (compound) is a donor type organic semiconductor (compound) represented typically by a hole-transporting organic compound, which has a tendency to release electrons. More specifically, when two organic materials are used in contact with each other, one that has a smaller ionization potential is the organic p-type semiconductor (compound). Accordingly, as the donor type organic compound, any organic compound may be used insofar as it has electron releasing or donating properties. On the other hand, the organic n-type semiconductor is an acceptor type organic semiconductor (compound) represented typically by an electron transporting organic compound, which has a tendency to accept electrons. More specifically, when two organic compounds are used in contact with each other, one that has a larger electron affinity is the organic n-type semiconductor. Accordingly, as the acceptor type organic compound, any organic compounds may be used insofar as it has the electron-accepting property.

Examples of materials applicable as the organic p-type and n-type semiconductors and the structure of the photoelectric conversion film 46c are described in detail in JPA 2009-32854 (U.S. Pat. No. 7,847,258). Therefore, the detailed description thereof will be omitted here.

The photoelectric converter 46 may include at least a pair of electrodes 46a and 46b and a photoelectric conversion film 46c. In order to inhibit a dark current from increasing, the photoelectric convertor 46 preferably includes at least one of an electron-blocking film and a hole-blocking film, and more preferably both of these films.

The electron-blocking film may be disposed between the upper electrode 46b and the photoelectric conversion film 46c. When a bias voltage is applied across the lower and upper electrodes 46a and 46b, the electron-blocking film prevents injection of electrons from the upper electrode 46b into the photoelectric conversion film 46c, the injected electrons increasing the dark current. Electron-releasing organic materials may be used for the electron-blocking film. In practice, the material for the electron-blocking film may be selected depending on the materials of the adjacent electrode and the adjacent photoelectric conversion film 46c, and etc. A material that has an electron affinity (Ea) larger by 1.3 eV or more than the work function (Wf) of the material of the adjacent electrode and also has an ionization potential (Ip) the same as or smaller than the Ip of the material of the adjacent photoelectric conversion film 46c is preferable. The electron-releasing organic materials applicable to the electron-blocking film are described in detail in the above-mentioned JPA 2009-32854. Therefore, the description thereof will be omitted here.

The thickness of the electron-blocking film is, in order to exert the dark current inhibition effect and prevent lowering the efficiency of photoelectric conversion in the photoelectric converter 46, preferably in a range of 10 nm to 200 nm, more preferably 30 nm to 150 nm, and most preferably 50 nm to 100 nm.

The hole-blocking film may be disposed between the lower electrode 46b and the photoelectric conversion film 46c, to prevent holes from being injected from the lower electrode 46b into the photoelectric conversion film 46c when a bias voltage is applied across the electrodes 46a and 46b. Thereby, the hole-blocking film prevents an increase in dark current. The hole-blocking film may be made of an electron-accepting organic material. In practice, the material for the hole-blocking film may be selected depending on the materials of the adjacent electrode and the adjacent photoelectric conversion film 46c and etc. A material that has an ionization potential (Ip) larger by 1.3 eV or more than the work function (Wf) of the material of the adjacent electrode and an electron affinity (Ea) the same as or larger than the Ea of the material of the adjacent photoelectric conversion film 46c is preferable. The electron-accepting organic materials applicable to the hole-blocking film are described in detail in the above-mentioned JPA 2009-32854. Therefore, the description thereof will be omitted here.

The thickness of the hole-blocking film is, in order to exert the dark current inhibition effect and prevent lowering the efficiency of photoelectric conversion in the photoelectric converter 46, preferably in a range of 10 nm to 200 nm, more preferably 30 nm to 150 nm, and most preferably 50 nm to 100 nm.

When a bias voltage is applied in such a manner that, among electric charges generated in the photoelectric conversion film 46c, holes will move to the lower electrode 46a and electrons will move to the upper electrode 46b, the electron-blocking film and the hole-blocking film may be positioned in reverse order. Furthermore, it is not necessarily provide both of the electron-blocking film and the hole-blocking film. Only one of these films may provide the dark current inhibition effect to some extent.

As amorphous oxides available for forming the active layer 24, oxides containing at least one of In, Ga and Zn (such as In—O series) are preferred, oxides containing at least two of In, Ga and Zn (such as In—Zn—O series, In—Ga—O series, Ga—Zn—O series) are more preferred, and oxides containing In, Ga and Zn are particularly preferred. As the In—Ga—Zn—O series amorphous oxides, amorphous oxides of which crystalline composition is expressed by InGaO3 (ZnO)m (m: natural number less than 6) are preferred and, in particular, InGaZnO4 is more preferred. However, the amorphous oxides for forming the active layer are not limited to these.

Organic semiconductors available for forming the active layer 24 may include phthalocyanine compounds, pentacene and vanadyl phthalocyanine, but are not limited to these. The composition of phthalocyanine compounds is described in detail in JPA 2009-212389 (U.S. Pat. No. 7,768,002).

The active layer of the TFT 47, formed from any of amorphous oxides, organic semiconductor materials and carbon nanotubes, will not or very little absorb radiations such as X-rays, noise generation can be effectively suppressed.

The active layer formed from a carbon nanotube can accelerate the switching of the TFT and lower the absorbance to the visible light in the TFT 47. However, if any metallic impurity is mixed into the carbon nanotube active layer, the performance of the TFT 47 will drastically degrade even with a very small amount of contaminant. Therefore, the carbon nanotube for forming the active layer must be highly purified, for example, through centrifugal separation.

Because either the organic photoelectric conversion material or the organic semiconductor material can provide sufficiently flexible film, if the photoelectric conversion film 46c is formed from an organic photoelectric conversion material and combined with the TFT 47 of which the active layer is formed from an organic semiconductor material, the sensor panel 23 may not necessarily have high rigidity even while the sensor panel 23 must bear the weight of the test subject like a patient.

The sensor substrate 33 may be made of any material insofar as it is light-permeable and little absorbs radiations. In view of the fact that both the active layers of the TFTs 47 and the photoelectric conversion films 46c may be formed respectively from an amorphous oxide and an organic photoelectric conversion material under low temperature, the sensor substrate 33 should not be limited to a highly heat-resistant substrate such as a semiconductor substrate, quartz substrate or a glass substrate, but the sensor substrate 33 may be a flexible substrate made from synthetic resin, aramid, or bionanofibers. Specifically, the synthetic resins for the flexible substrate may include polyesters, such as polyethylene terephthalate, polybutylene phthalate and polyethylene naphthalate, polystyrenes, polycarbonate, polyether sulfone, polyarylate, polyimide, polycycloolefin, poly(chlorotrifluoroethylene), norbornene resins. Using the flexible resin substrate for the sensor substrate 33 can reduce the weight of the radiation detector 19 and improve the portability of the radiographic device 10. The sensor substrate 33 may also be provided with other layers, such as an insulating layer for ensuring electrical insulation, a gas barrier layer for shielding against moisture and oxygen, or an undercoating layer for improving flatness or adhesiveness to the electrodes and the like.

Because the sensor substrate 33 may be formed from aramid using a high temperature process at 200 degrees or more, the transparent material for the electrodes may be cured at the high temperature, so that the resistance of the electrodes may be reduced. Moreover, automatic fabrication of the driver IC on the substrate, which includes a solder reflow process, becomes available. Furthermore, as having a similar thermal expansion coefficient to those of ITO (indium tin oxide) and the glass substrate, the substrate formed from aramid will hardly suffer a warp or a crack. In addition, aramid permits producing a thinner substrate than other materials like glass. The sensor substrate 33 may also be formed by laminating an extra-thin glass substrate and an aramid layer.

Bionanofiber is a complex of cellulose microfibril bunch (bacteria cellulose), which is produced by bacteria (acetobacter xylinum), and a transparent resin. The cellulose microfibril bunch has a width of 50 nm, a size of 1/10 to the wavelength of visible light, a high strength, a high resiliency, and a low thermal expansion. Impregnating a transparent resin, such as acryl resin or epoxy resin, into bacteria cellulose and then curing it will produce bionanofibers, which contain 60% to 70% fibers but provide a transparency of about 90% to light at 500 nm wavelengths. The bionanofibers has a low thermal expansion coefficient (3 to 7 ppm) comparable to that of silicon crystal, as high strength (460 MPa) as that of steel, and high resiliency (30 GPa) and flexibility. Therefore, bionanofibers can make the sensor substrate 33 thinner than other materials like glass.

When the sensor substrate 33 is made of a glass substrate, the total thickness of the sensor panel 23 may for example be 0.7 mm or so. If a thinner substrate made of a transparent resin is used as the sensor substrate 33, the total thickness of the sensor panel 23 may for example be reduced to 0.1 mm or so, and the sensor panel 23 may be made flexible. The flexible sensor panel 23 will make the radiographic device 10 more impact-resistant. Because plastic resins, aramid and bionanofibers have low absorbance to radiations, the sensor substrate 33 made of any of these materials will not so much absorb radiations that the sensitivity of the sensor panel 23 to radiations will not so much decrease even in the ISS type where the radiations pass through the sensor panel 23 before being detected.

Although the sensor panel 23 includes the photosensor 34 that consists of the photoelectric converter 46 and the TFT 47 in the above embodiment, a CMOS sensor or an organic CMOS sensor using an organic photoelectric conversion material for its photoelectric converters (photodiodes) may be used as the photosensor. Since the CMOS sensor and the organic CMOS sensor use single-crystalline silicon for the substrate, the carrier transporting speed in the CMOS or the organic CMOS sensor is three or four orders of magnitude higher than the speed in the amorphous silicon photoelectric converter, and also the radiolucency of the CMOS or the organic CMOS sensor is higher than the amorphous silicon photoelectric converter. Therefore, the CMOS or the organic CMOS sensor is suitable for the ISS type radiation detector. Since the detail of organic CMOS sensor has been described in JPA 2009-212733 (U.S. Patent Application No. 2009/0224162), the description thereof will be omitted here.

In order to make the CMOS or the organic CMOS sensor flexible, the CMOS or the organic CMOS sensor may be constituted of organic thin film transistors formed on a sheet of plastic film. Since the detail of the organic thin film transistor has been described in an article “Flexible Organic Transistors and Circuits with Extreme Bending Stability” by Tsuyoshi Sekitani, Nature Materials 9, p. 1015-1022, on Nov. 7, 2010.

Alternatively, in order to make the CMOS or the organic CMOS sensor flexible, such photodiodes and transistors that are formed of single-crystalline silicon may be disposed on a flexible plastic substrate to constitute the CMOS or the organic CMOS sensor. As a method of disposing the photodiodes and the transistors on the plastic substrate, for example, the fluidic self-assembly (FSA) method is applicable, wherein device blocks of tens of microns in size are sparged onto an appropriate substrate in a solution, so as to be arranged in requisite positions. The detailed description of the FSA method will be omitted here, since it has been described in detail in an article “Fabrication of Resonant Tunneling Device Blocks for Fluidic Self-Assembly” by Koichi MAEZAWA, IEICE Technical Report on electronic devices, Vol. 108, No. 87, p. 67-71, published by the Institute of Electronics, Information and Communication Engineers Inc., on Jun. 6, 2008.

Although the present invention has been described with reference to the radiation detector of which scintillator is constituted of columnar crystals, the present invention is applicable to radiation detectors using other kinds of scintillators. Although the above embodiments have been described with respect to ISS type radiation detectors, the present invention is applicable to PSS type radiation detectors. While the radiation detector is mounted in the cassette-sized housing in the above embodiment, the radiation detector may also be mounted in a radiographic stand for imaging in the upright posture, a radiographic table for imaging in the lateral posture, or in a mammography machine.

It should be understood that the embodiments of the present invention have been disclosed for illustrative purposes only. Those skilled in the art will appreciate that various modifications, additions and substitutions are possible without departing from the scope and spirit of the invention as disclosed in the accompanying claims.

What is claimed is:

1. A radiographic device comprising:
a scintillator for converting incident radiations to light;
a sensor panel having a photosensor for detecting the light obtained through the conversion of the incident radiations by the scintillator, the sensor panel being placed on a light emitting side of the scintillator; and
a reflector layer placed on the opposite side of the scintillator to the light emitting side, the reflector layer being configured to selectively reflect the light from the scintillator toward the light emitting side either specularly or retroreflectively.

2. The radiographic device as recited in claim 1, wherein the reflector layer reflects the light from the scintillator either specularly or retroreflectively depending on the wavelength of the light.

3. The radiographic device as recited in claim 2, wherein the reflector layer specularly reflects short-wavelength components of the light and retroreflects long-wavelength components of the light.

4. The radiographic device as recited in claim 3, wherein the reflector layer comprises a first reflective layer that specularly reflects the short-wavelength components of the light and lets the long-wavelength components of the light pass through it, and a second reflective layer that retroreflects the long-wavelength components of the light after passing through the first reflective layer.

5. The radiographic device as recited in claim 4, wherein the first reflective layer is constructed as a dichroic filter.

6. The radiographic device as recited in claim 4, wherein the first reflective layer and the second reflective layer are laminated such that a scintillator panel is disposed on one surface of the first reflective layer and the second reflective layer is disposed on the other surface of the first reflective layer.

7. The radiographic device as recited in claim 6, wherein the second reflective layer is coated with retroreflective material containing glass beads.

8. The radiographic device as recited in claim 6, wherein the second reflective layer has numbers of micro prisms on its surface.

9. The radiographic device as recited in claim 6, further comprising a protective film covering up the scintillator panel, such that the first reflective layer is kept in tight contact with the scintillator panel by adhesive power of the protective film.

10. The radiographic device as recited in claim 6, wherein the first reflective layer is bonded to the scintillator panel with a transparent adhesive.

11. The radiographic device as recited in claim 6, wherein the first reflective layer is bonded to the second reflective layer with a transparent adhesive.

12. The radiographic device as recited in claim 1, wherein the sensor panel is placed on an irradiated side of the scintillator so that the radiations are incident into the scintillator after penetrating the sensor panel.

13. The radiographic device as recited in claim 1, wherein the scintillator comprises multiple columnar crystals oriented substantially vertically to the sensor panel.

14. The radiographic device as recited in claim 13, wherein the scintillator is formed from thallium-doped cesium iodide.

15. The radiographic device as recited in claim 1, wherein the sensor panel is a CMOS sensor using an organic photoelectric conversion material.

16. A method of manufacturing a radiographic device including a scintillator for converting incident radiations to light and a sensor panel having a photosensor for detecting the light obtained through the conversion of the incident radiations by the scintillator, the method comprising the steps of:
forming the scintillator on one side of the sensor panel; and
providing a reflector layer on the opposite side of the scintillator to the sensor panel, the reflector layer selectively reflecting the light from the scintillator either specularly or retroreflectively.

17. The method as recited in claim 16, wherein the reflector layer is comprised of a first reflective layer that specularly reflects the short-wavelength components of the light and lets the long-wavelength components of the light pass through it, and a second reflective layer that retroreflects the long-wavelength components of the light after passing through the first reflective layer.

18. A method of manufacturing a radiographic device including a scintillator for converting incident radiations to light and a sensor panel having a photosensor for detecting the light obtained through the conversion of the incident radiations by the scintillator, the method comprising the steps of:
forming the scintillator on a light-permeable substrate;
providing a reflector layer on the substrate such that the reflector layer selectively reflects the light from the scintillator either specularly or retroreflectively; and
bonding the scintillator and the sensor panel together.

19. The method as recited in claim 18, wherein the reflector layer is comprised of a first reflective layer that specularly reflects the short-wavelength components of the light and lets the long-wavelength components of the light pass through it, and a second reflective layer that retroreflects the long-wavelength components of the light after passing through the first reflective layer.
